(19) United States
(12) Patent Application Publication
(10) Pub. No.: US 2026/0344373 A1
(43) Pub. Date: Oct. 29, 2026

(54) METHOD FOR MANUFACTURING MASK PATTERN AND SEMICONDUCTOR DEVICE

(71) Applicant: SK hynix Inc., Gyeonggi-do (KR)

(72) Inventor: Young In BAE, Gyeonggi-do (KR)

(21) Appl. No.: 19/530,372

(22) Filed: Feb. 5, 2026

(30) Foreign Application Priority Data
Apr. 25, 2025 (KR) 10-2025-0054707

(51) Int. Cl. H10P 76/40; H10P 50/00

(52) U.S. Cl. CPC H10P 76/405; H10P 50/69; H10P 50/73

(57) ABSTRACT

A method for forming a mask pattern includes forming a hard mask layer over a etch target layer to be etched; and forming a plurality of hard mask patterns over the hard mask layer. The hard mask layer includes a first layer disposed below the plurality of hard mask patterns, and a second layer disposed between the first layer and the etch target layer. A concentration of boron included in the first layer is lower than a concentration of boron included in the second layer.

### CROSS-REFERENCE TO RELATED APPLICATION

This patent application claims the priority and benefits of Korean patent application No. 10-2025-0054707, filed on Apr. 25, 2025, the disclosure of which is incorporated herein by reference in its entirety.

### TECHNICAL FIELD

The embodiments of the present disclosure generally relate to a mask pattern and a method for manufacturing a semiconductor device using the mask pattern.

### BACKGROUND

As the degree of integration of semiconductor devices increases, the difficulty in designing integrated circuits (ICs) is growing exponentially.

During the development of semiconductor devices, the number of devices included per unit chip area is rapidly increasing while the size of each device is being gradually reduced, and this high degree of integration in semiconductor devices results in increase in the complexity of integrated circuit (IC) processing and IC fabrication.

For example, as the size of semiconductor devices decreases, miniaturization of mask patterns to be used in semiconductor fabrication processes may be required. However, the miniaturization and increased aspect ratio of hard mask patterns used in a mask pattern fabrication process may lead to defects such as leaning of the hard mask patterns. When leaning of the hard mask patterns occurs, undesired etching may occur during subsequent etching processes. As a result, defective mask patterns may occur, thereby potentially causing damage to semiconductor devices.

### SUMMARY

Various embodiments of the present disclosure relate to technology that can prevent defects in a hard mask pattern by forming a hard mask layer having a plurality of layers.

In accordance with an embodiment of the present disclosure, a method for forming a mask pattern may include forming a hard mask layer over an etch target layer to be etched; and forming a plurality of hard mask patterns over the hard mask layer, wherein the hard mask layer includes a first layer disposed below the plurality of hard mask patterns, and a second layer disposed between the first layer and the etch target layer, and wherein a concentration of boron included in the first layer is lower than a concentration of boron included in the second layer.

In some embodiments, the first layer may have a thinner thickness than the second layer.

In some embodiments, the boron concentration of the first layer may be less than about 45 atomic %.

In some embodiments, the boron concentration of the second layer may be greater than about 55 atomic %.

In some embodiments, the plurality of hard mask patterns may include silicon oxide.

In some embodiments, the hard mask layer may further include a third layer disposed below the second layer; and a fourth layer disposed between the third layer and the etch target layer.

In some embodiments, the third layer may have a higher density than the fourth layer.

In some embodiments, the first layer and the second layer may be formed at a temperature of about 400°C or higher.

In some embodiments, the plurality of hard mask patterns may be spaced apart from each other by a predetermined distance.

In some embodiments, a thickness of the third layer may be thicker than a thickness of the first layer and less than a thickness of the fourth layer.

In some embodiments, a thickness of the fourth layer may be thicker than a thickness of the second layer.

In some embodiments, the plurality of hard mask patterns may be formed by forming a sacrificial mask pattern over the first layer; forming a pre-pattern layer overlapping top and side surfaces of the sacrificial mask pattern; and selectively etching the pre-pattern layer.

In accordance with another embodiment of the present disclosure, a method for manufacturing a semiconductor device may include forming a hard mask layer over an etch target layer; forming a sacrificial mask pattern over the hard mask layer; forming a pre-pattern layer overlapping top and side surfaces of the sacrificial mask pattern; forming a plurality of hard mask patterns by selectively etching the pre-pattern layer; removing the sacrificial mask pattern; and etching the hard mask layer using the plurality of hard mask patterns as an etch mask. The hard mask layer may include a first layer contacting a lower portion of the sacrificial mask pattern and a second layer contacting a lower portion of the first layer. A concentration of boron included in the first layer may be lower than a concentration of boron included in the second layer.

In some embodiments, the hard mask layer may be formed by forming a fourth layer over the etch target layer; forming a third layer over the fourth layer; forming the second layer over the third layer; and forming the first layer over the second layer.

In some embodiments, the boron concentration of the first layer may be less than about 45 atomic %.

In some embodiments, the boron concentration of the second layer may be greater than about 55 atomic %.

In some embodiments, the first layer and the second layer may be formed at a temperature of about 400°C or higher.

In accordance with another embodiment of the present disclosure, a method for manufacturing a semiconductor device may comprise forming a hard mask layer disposed over a target layer, and forming at least one hard mask pattern over the hard mask layer, wherein the hard mask layer comprises a first layer, a second layer below the first layer, a third layer below the second layer, and a fourth layer between the third layer and the target layer, wherein the first layer includes boron with a boron concentration of the first layer being less than about 45 atomic %, wherein the second layer has a relatively higher density than the third layer, and wherein the target layer is an etch target layer in which a semiconductor pattern is to be formed using the hard mask as an etch mask.

In some embodiments, the second layer may include boron with a boron concentration of the second layer being greater than about 55 atomic %.

In some embodiments, a density of the third layer is higher than a density of the fourth layer.

It is to be understood that both the foregoing general description and the following detailed description of the present disclosure are illustrative and descriptive and are intended to provide further description of the embodiments of the present disclosure as claimed.

### BRIEF DESCRIPTION OF THE DRAWINGS

The above and other features and beneficial aspects of the present disclosure will become readily apparent with reference to the following detailed description when considered in conjunction with the accompanying drawings.

FIG. 1 is a cross-sectional view illustrating a hard mask layer according to an embodiment of the present disclosure.

FIG. 2 is a cross-sectional view illustrating a hard mask layer according to another embodiment of the present disclosure.

FIGS. 3A -3K are cross-sectional views illustrating a method for forming a semiconductor device according to an embodiment of the present disclosure.

FIG. 4 is a flowchart illustrating a method for manufacturing a semiconductor device according to an embodiment of the present disclosure.

### DETAILED DESCRIPTION

The present disclosure provides embodiments and examples of a mask pattern and a method for manufacturing a semiconductor device using the mask pattern that may be used in configurations to substantially address one or more technical or engineering issues and to mitigate limitations or disadvantages encountered in some other semiconductor devices. Some embodiments of the present disclosure relate to technology that can prevent defects in a hard mask pattern by forming a hard mask layer having a plurality of layers. In recognition of the issues above, the present disclosure provides technology that can enable a concentration of boron included in a layer contacting the hard mask pattern among the plurality of layers included in the hard mask layer to be lower than that of the layer spaced apart from the hard mask pattern, so that adhesion to the hard mask pattern is improved, thereby preventing leaning of an upper portion of the hard mask pattern. The present disclosure provides technology that can enable a concentration of boron included in the layer spaced apart from the hard mask pattern to be set to a relatively high concentration, can adjust the etch selectivity, and can prevent damage to a top surface of a layer to be etched. The present disclosure provides technology that can prevent leaning of the hard mask pattern, thereby preventing top surface damage (top attack) of the layer to be etched.

Reference will now be made in detail to the embodiments of the present disclosure which are illustrated in the accompanying drawings. Wherever possible, the same reference numbers will be used throughout the drawings to refer to the same or like parts. While the embodiments of the present disclosure are susceptible to various modifications and alternative forms, specific embodiments thereof are shown in the drawings. However, the embodiments should not be construed as being limited to the embodiments set forth herein.

Hereinafter, various embodiments will be described with reference to the accompanying drawings. However, it should be understood that the embodiments are not limited to specific embodiments, but include various modifications, equivalents and/or alternatives of the embodiments. The embodiments of the present disclosure may provide a variety of advantageous effects capable of being directly or indirectly recognized by one of ordinary skill in the art.

The drawings are not necessarily depicted to scale, and in some drawings, proportions of at least some of the illustrated structures may be exaggerated to clearly show features of the embodiments. When a multilayer structure having two or more layers is disclosed in the drawings or detailed description, the relative positional relationship or arrangement order of the illustrated layers reflects only specific embodiments and should not be construed as limiting the technical spirit disclosed in the present specification, and the relative positional relationship or arrangement order of the layers may vary. In addition, the drawings or detailed descriptions of the multilayer structures may not reflect all layers present in a specific multilayer structure (for example, one or more additional layers may exist between the two illustrated layers). For instance, in a multilayer structure described in the drawings or the detailed description, when a first layer is described as being on a second layer or on a substrate, it may indicate that the first layer is formed directly on the second layer or the substrate, or that one or more other layers may be present between the first and second layers, or between the first layer and the substrate.

Hereinafter, a mask pattern and a method for manufacturing a semiconductor device using the mask pattern according to embodiments of the present disclosure will be described in detail with reference to the drawings.

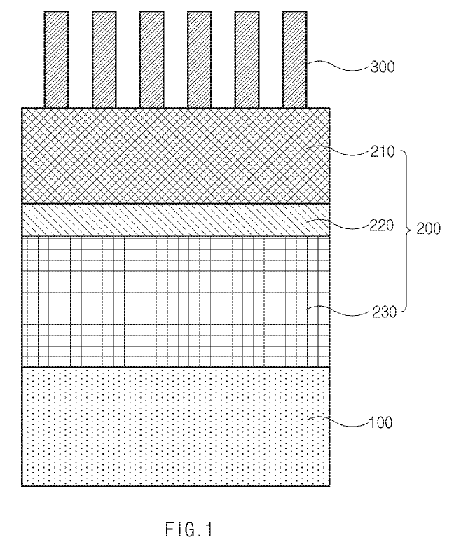

FIG. 1 is a cross-sectional view illustrating a hard mask layer according to an embodiment of the present disclosure.

Referring to FIG. 1, a hard mask layer 200 may be formed over a target layer 100 to be etched (hereinafter referred to as an etch target layer), and at least one hard mask pattern 300 may be formed over the hard mask layer 200.

The etch target layer 100 may include, for example, a semiconductor substrate such as a silicon wafer or a silicon-on-insulator (SOI) wafer. According to another embodiment, the etch target layer 100 may include a group III-V semiconductor substrate, for example, a compound semiconductor substrate such as a GaAs substrate.

According to another embodiment, the etch target layer 100 may include monocrystalline silicon, polysilicon, amorphous silicon, monocrystalline silicon germanium, polycrystalline silicon germanium, carbon-doped silicon, or a combination thereof.

According to another embodiment, the etch target layer 100 may include other materials (e.g., silicon oxide, etc.) except for a semiconductor substrate.

The hard mask layer 200 may overlap the etch target layer 100, and may include a plurality of layers. In FIG. 1, the hard mask layer 200 may include a first layer 210, a second layer 220, and a third layer 230.

The first layer 210 may be a polysilicon layer containing boron (B). For example, the first layer 210 may be formed at a temperature of about 300°C to about 500°C, and may have a thickness of approximately 450 Å. The concentration of boron (B) included in the first layer 210 may exceed, for example, about 55 atomic %. According to one embodiment, the concentration of boron (B) included in the first layer 210 may range from about 75 atomic % to about 95 atomic %.

The second layer 220 may be a layer disposed below the first layer 210. The second layer 220 may be a silicon oxide layer formed by conformal deposition. For example, the second layer 220 may have a thickness of approximately 100 Å.

The third layer 230 may be a layer disposed below the second layer 220. The third layer 230 may be an ultra-low-temperature oxide (ULTO) layer, and may have a thickness of approximately 650 Å, for example.

The second layer 220 may have a relatively higher density than the third layer 230.

As the second layer 220 is formed to have a higher density than the third layer 230, etching (also called “footing”) of an undesired region in the hard mask layer 200 can be prevented in the etching process of the hard mask layer 200, and wiggling (e.g., warping) of the etched hard mask can also be prevented in the etching process of the hard mask layer 200.

Each of the hard mask patterns 300 disposed over the hard mask layer 200 may be an ultra-low-temperature oxide (ULTO) layer. The hard mask patterns 300 may be spaced apart from each other by a predetermined distance.

According to an embodiment, the boron concentration of the first layer 210 may exceed 45 atomic %.

As the boron concentration exceeds 45 atomic %, the etch selectivity of the hard mask layer 200 may increase during etching of the hard mask layer 200. However, when the boron concentration in the first layer 210 exceeds 55 atomic %, leaning of the hard mask pattern 300 may occur.

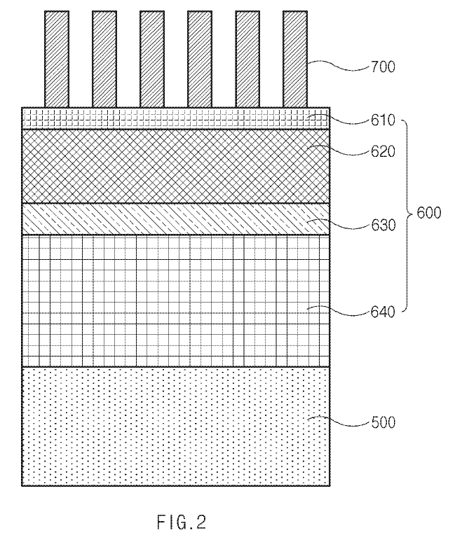

FIG. 2 is a cross-sectional view illustrating a hard mask layer according to another embodiment of the present disclosure.

Referring to FIG. 2, a hard mask layer 600 may be formed over an etch target layer 500, and at least one hard mask pattern 700 may be formed over the hard mask layer 600.

The etch target layer 500 of FIG. 2 is substantially the same as the etch target layer 100 of FIG. 1, and as such redundant description thereof will herein be omitted for brevity.

The hard mask layer 600 may overlap the etch target layer 500, and may include a plurality of layers. In the embodiment shown in FIG. 2, the hard mask layer 600 may include a first layer 610, a second layer 620, a third layer 630, and a fourth layer 640.

Unlike FIG. 1, the hard mask layer 600 shown in FIG. 2 may include additional layers, so that the embodiment of FIG. 2 may prevent leaning of the hard mask pattern 700.

In the embodiment of FIG. 2, each of the first layer 610 and the second layer 620 may be a polysilicon layer containing boron (B).

The first layer 610 may be a polysilicon layer formed at about 400°C. The boron concentration of the first layer 610 may be less than about 45 atomic %.

The second layer 620 may be disposed below the first layer 610, and may be a polysilicon layer formed at about 400°C. The boron concentration of the second layer 620 may exceed about 55 atomic %.

For example, the first layer 610 may have a thickness of 1/5 to 1/7 of the thickness of the second layer 620.

The hard mask layer 600 shown in FIG. 2 may include a plurality of boron-containing polysilicon layers (610, 620), and the boron concentrations of the two boron-containing polysilicon layers (610, 620) may be different from each other.

In addition, the first layer 610 and the second layer 620 included in the hard mask layer 600 of FIG. 2 may be formed at a higher temperature than the first layer 210 of FIG. 1.

The third layer 630 may be a layer disposed below the second layer 620. The third layer 630 may be a silicon oxide layer formed by conformal deposition.

The fourth layer 640 may be a layer disposed below the third layer 630. The fourth layer 640 may be an ultra-low-temperature oxide (ULTO) layer. For example, the third layer 630 may have a thickness of 1/6 to 1/7 of the thickness of the fourth layer 640.

The third layer 630 may have a relatively higher density than the fourth layer 640. As the third layer 630 is formed to have a higher density than the fourth layer 640, etching (also called “footing”) of an undesired region in the hard mask layer 600 can be prevented in the etching process of the hard mask layer 600, and wiggling (e.g., warping) of the etched hard mask can also be prevented in the etching process of the hard mask layer 600.

Each of the hard mask patterns 700 disposed over the hard mask layer 600 may be an ultra-low-temperature oxide (ULTO) layer. The hard mask patterns 700 may be spaced apart from each other by a predetermined distance.

According to an embodiment of the present disclosure, since the boron concentration of the first layer 610 is less than about 45 atomic % and the boron concentration of the second layer 620 is greater than about 55 atomic %, the hard mask layer 600 may prevent leaning of the hard mask patterns 700 and at the same time may be formed to have an improved etch selectivity.

The hard mask layer 600 according to an embodiment of the present disclosure may enable the boron concentration of a region (e.g., the first layer 610) contacting the hard mask patterns 700 to be kept at a low concentration, thereby allowing the hard mask pattern 700 and the hard mask layer 600 to adhere to each other more effectively.

When the hard mask pattern 700 and the hard mask layer 600 are well adhered to each other, leaning of the hard mask pattern 700 can be effectively prevented. Leaning of a hard mask pattern typically refers to a slight tilt or misalignment of the patterned mask features during a photolithography or etching process. This leaning can occur when the vertical edges of the mask pattern are not perfectly perpendicular to the substrate, resulting in angled or sloped sidewalls in the transferred pattern. Leaning can affect the critical dimensions of the device features, potentially leading to performance issues or yield loss. Preventing leaning is an important effect of the present invention allowing maintaining pattern fidelity, especially as feature sizes shrink.

In addition, the boron concentration in a region not bonded to the hard mask pattern 700 (e.g., the second layer 620) may increase, so that the etch selectivity in the etching process may be improved.

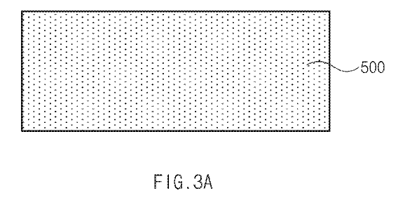

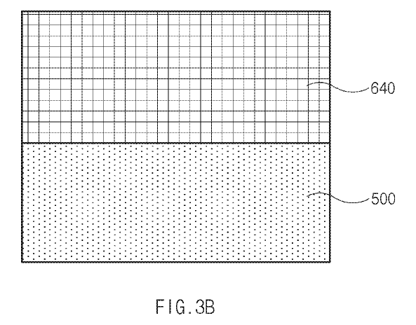

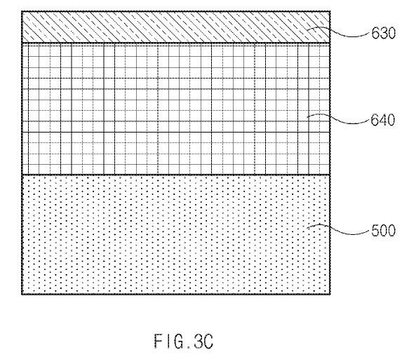

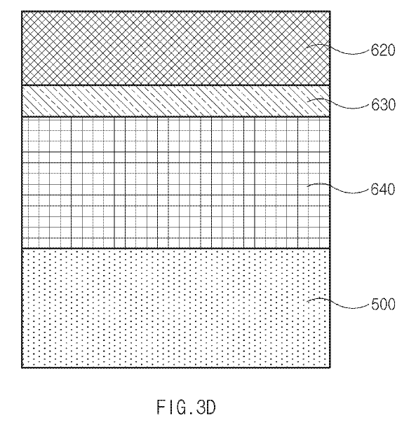

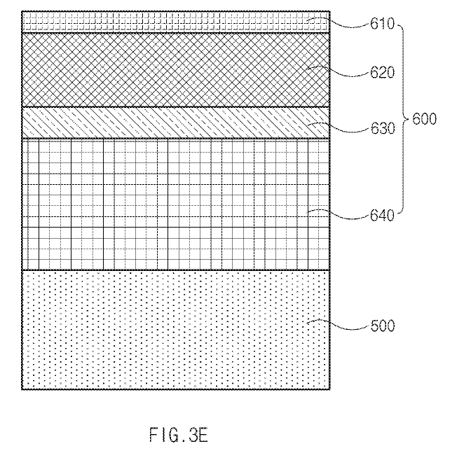

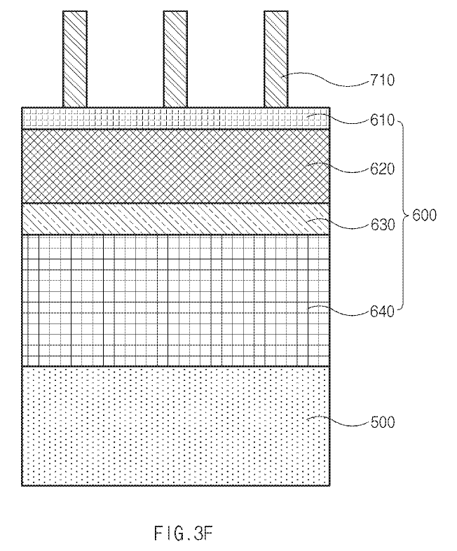

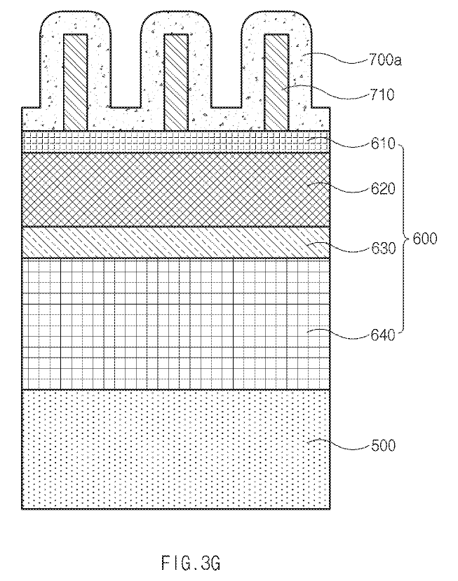

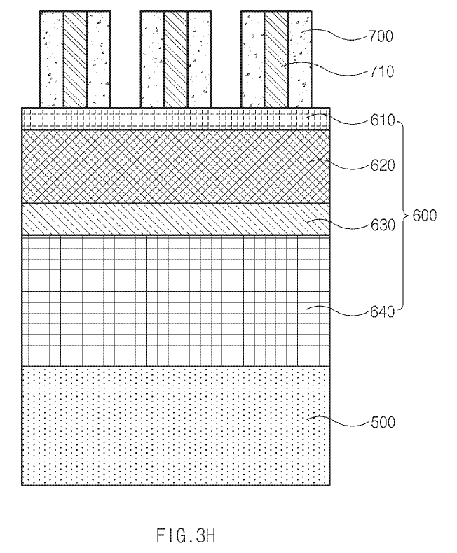

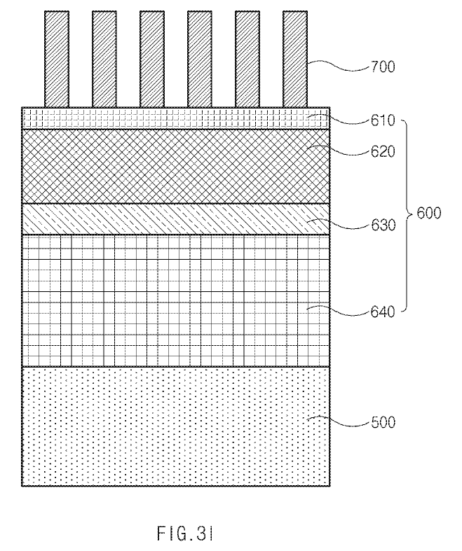

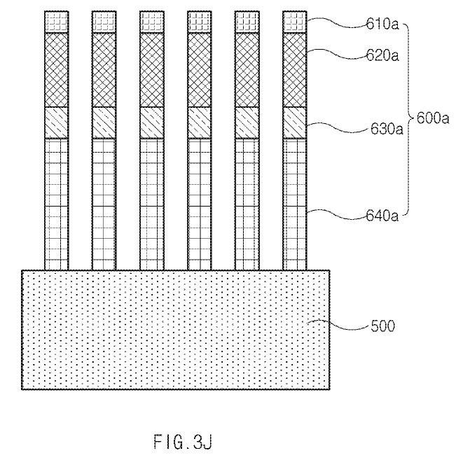

FIGS. 3A - 3K are cross-sectional views illustrating a method for forming a semiconductor device according to an embodiment of the present disclosure.

Referring to FIG. 3A, an etch target layer 500, in which a semiconductor pattern is to be formed using a hard mask (not shown) as an etch mask, is illustrated. As previously described above, the etch target layer 500 may include a silicon wafer, a Silicon-On-Insulator (SOI), a group III-V compound semiconductor substrate, monocrystalline silicon, polysilicon, amorphous silicon, monocrystalline silicon germanium, polycrystalline silicon germanium, carbon-doped silicon, or a combination thereof.

In FIG. 3B, a process in which a fourth layer 640 is formed over the etch target layer 500 is illustrated. The fourth layer 640 may be an ultra-low-temperature oxide (ULTO) layer. For example, the ULTO layer may be formed at a low temperature ranging from about 50°C to about 150°C.

In FIG. 3C, a process in which a third layer 630 is formed over the fourth layer 640 is illustrated. The third layer 630 may be a silicon oxide layer formed through a conformal deposition process.

As the third layer 630 is formed by the conformal deposition process, the third layer 830 may have a higher density than the fourth layer 640 formed of the ULTO layer.

When the third layer 630 is formed to have a higher density than the fourth layer 640, occurrence of undesired etching (footing) of the fourth layer 640 may be prevented after completion of the etching process.

In FIG. 3D, a process in which a second layer 620 is formed over the third layer 630 is illustrated. The second layer 620 may be a polysilicon layer containing boron, and may be formed at a temperature of about 400°C or higher. The boron concentration of the second layer 620 may exceed 55%, for example.

In FIG. 3E, a process in which a first layer 610 is formed over the second layer 620 is illustrated. The first layer 610 may be a polysilicon layer containing boron, and may be formed at a temperature of about 400°C or higher. The boron concentration of the first layer 610 may be less than about 45 atomic %, for example.

As the first layer 610 is formed to have a lower boron concentration than the second layer 620, the adhesion between a pre-pattern layer 700a to be formed in a subsequent process and the first layer 610 may be improved. When the adhesion between the pre-pattern layer 700a and the first layer 610 increases, the adhesion between the hard mask pattern 700, which is formed based on the pre-pattern layer 700a, and the first layer 610 may also increase.

In FIG. 3F, a process in which a sacrificial mask pattern 710 is formed over the first layer 610 is illustrated. The sacrificial mask pattern 710 may include, for example, photoresist or carbon.

In FIG. 3G, a pre-pattern layer 700a may be formed to overlap the top and side surfaces of the sacrificial mask pattern 710.

The pre-pattern layer 700a may be, for example, a silicon oxide layer formed by an atomic layer deposition (ALD) process. The pre-pattern layer 700a may be an ultra-low-temperature oxide (ULTO) layer, and may be formed at a low temperature ranging from 50°C to 130°C, for example.

In FIG. 3H, at least a portion of the pre-pattern layer 700a may be etched. For example, at least a portion of the pre-pattern layer 700a may be removed by anisotropic etching.

In FIG. 3I, the sacrificial mask pattern 710 (see FIG. 3G) may be removed. The process for removing the sacrificial mask pattern may include, for example, an ashing process. As the sacrificial mask pattern is removed, only the plurality of hard mask patterns 700 may remain on the top of the hard mask layer 600.

In FIG. 3J, at least one hard mask 600a may be formed through an etching process. The hard mask 600a may be formed by partially removing the hard mask layer 600 using the hard mask pattern 700 as an etch mask. For example, at least some regions of the hard mask layer 600 may be removed through anisotropic etching.

The hard mask pattern 700 may be partially or entirely removed during the anisotropic etching process.

In the etching process using the hard mask pattern 700 as an etch mask, the first layer 610 and the second layer 620 may be etched, thereby exposing the third layer 630. At this time, as the third layer 630 is formed to have a higher density than the fourth layer 640, damage to the fourth layer 640 by the third layer 630 may be improved.

In addition, as the second layer 620 is formed to have a higher concentration than the first layer 610, damage to the third layer 630 and the fourth layer 640 may be prevented during the etching process.

The hard masks 600a may be aligned in a direction perpendicular to one surface of the etch target layer 500, and may be spaced apart from each other by a predetermined distance.

In FIG. 3K, a trench (T) may be formed in at least a portion of the etch target layer 500 using the hard mask 600a as an etch mask. A process for forming the trench (T) may include an anisotropic etching process, a directional etching process, an isotropic etching process, or a combination thereof. For example, the trench (T) may define at least a portion of a semiconductor pattern included in the semiconductor device.

For example, the trench region (T) may be gap-filled with an insulation material, and may serve as a region in which an isolation layer included in the semiconductor device is formed.

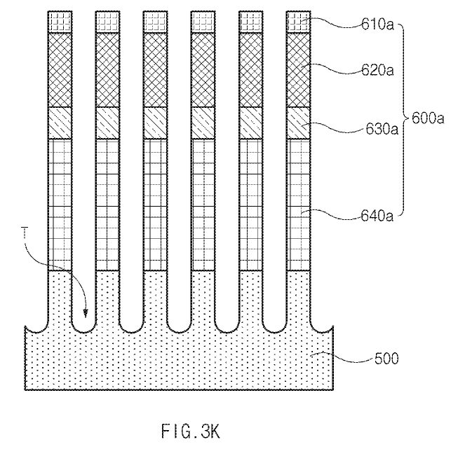

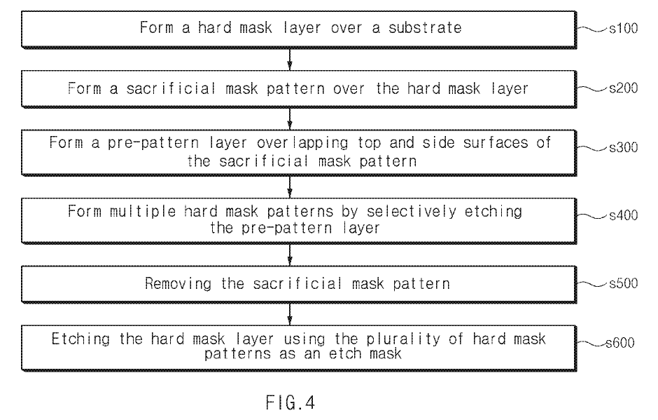

FIG. 4 is a flowchart illustrating a method for manufacturing the semiconductor device according to an embodiment of the present disclosure.

Referring to FIG. 4, a method for manufacturing the semiconductor device according to an embodiment of the present disclosure may include forming a hard mask layer over a substrate (Operation S100); forming a sacrificial mask pattern over the hard mask layer (Operation S200); forming a pre-pattern layer overlapping the top and side surfaces of the sacrificial mask pattern (Operation S300); selectively etching the pre-pattern layer to form a plurality of hard mask patterns (Operation S400); removing the sacrificial mask pattern (Operation S500); and etching the hard mask layer using the plurality of hard mask patterns as an etch mask (Operation S600).

The method for manufacturing the semiconductor device according to an embodiment of the present disclosure may further include forming a semiconductor pattern in the substrate using the hard mask (formed by etching the hard mask layer) as an etch mask.

In addition, the hard mask layer according to an embodiment of the present disclosure may include a plurality of layers, and the boron concentration of the first layer contacting a lower portion of the sacrificial mask pattern may be lower than the boron concentration of the second layer contacting a lower portion of the first layer.

According to an embodiment, the hard mask layer may be formed by sequentially forming a fourth layer, which is a ULTO layer, over the substrate; forming a third layer, which is an oxide layer formed by conformal deposition, over the fourth layer; forming a second layer, which is a polysilicon layer containing boron, over the third layer; and forming a first layer, which is a polysilicon layer containing boron, over the second layer. In addition, the first and second layers may be formed through high-temperature processes at about 400°C or higher.

As is apparent from the above description, the embodiments of the present disclosure may enable concentration of boron included in a layer contacting the hard mask pattern among the plurality of layers included in the hard mask layer to be lower than that of the layer spaced apart from the hard mask pattern, so that adhesion to the hard mask pattern is improved, thereby preventing leaning of an upper portion of the hard mask pattern.

The embodiments of the present disclosure may enable the concentration of the boron that is included in the layer that is spaced apart from the hard mask pattern to be set to a relatively high concentration, may adjust the etch selectivity, and may prevent damage to a top surface of a layer to be etched.

The embodiments of the present disclosure may prevent leaning of the hard mask pattern, thereby preventing top surface damage (top attack) of the layer to be etched.

The embodiments of the present disclosure may provide a variety of advantageous effects capable of being directly or indirectly recognized by one of ordinary skill in the art.

Those skilled in the art will appreciate that the present disclosure may be carried out in other specific ways than those set forth herein. In addition, claims that are not explicitly presented in the appended claims may be presented in combination as an embodiment or included as a new claim by a subsequent amendment after the application is filed.

Although a number of illustrative embodiments have been described, it should be understood that modifications and enhancements to the disclosed embodiments and other embodiments can be devised based on what is described and/or illustrated in the present disclosure. Furthermore, the embodiments may be combined to form additional embodiments.

What is claimed is:

1. A method for forming a mask pattern, the method comprising:
forming a hard mask layer over an etch target layer to be etched; and
forming a plurality of hard mask patterns over the hard mask layer,
wherein the hard mask layer includes a first layer disposed below the plurality of hard mask patterns, and a second layer disposed between the first layer and the etch target layer, and
wherein a concentration of boron included in the first layer is lower than a concentration of boron included in the second layer.

2. The method according to claim 1, wherein
a thickness of the first layer is thinner than a thickness of the second layer.

3. The method according to claim 1, wherein
the boron concentration of the first layer is less than about 45 atomic %.

4. The method according to claim 1, wherein
the boron concentration of the second layer is greater than about 55 atomic %.

5. The method according to claim 1, wherein
the plurality of hard mask patterns includes silicon oxide.

6. The method according to claim 1, wherein the hard mask layer further includes:
a third layer disposed below the second layer; and
a fourth layer disposed between the third layer and the etch target layer.

7. The method according to claim 6, wherein
a density of the third layer is higher than a density of the fourth layer.

8. The method according to claim 1, wherein
the first layer and the second layer are formed at a temperature of about 400°C or higher.

9. The method according to claim 1, wherein
the plurality of hard mask patterns is spaced apart from each other by a predetermined distance.

10. The method according to claim 6, wherein
a thickness of the third layer is greater than a thickness of the first layer and less than a thickness of the fourth layer.

11. The method according to claim 6, wherein
a thickness of the fourth layer is thicker than a thickness of the second layer.

12. The method according to claim 1, wherein the plurality of hard mask patterns is formed by:
forming a sacrificial mask pattern over the first layer;
forming a pre-pattern layer overlapping top and side surfaces of the sacrificial mask pattern; and
selectively etching the pre-pattern layer.

13. A method for manufacturing a semiconductor device, the method comprising:
forming a hard mask layer over an etch target layer;
forming a sacrificial mask pattern over the hard mask layer;
forming a pre-pattern layer overlapping top and side surfaces of the sacrificial mask pattern;
forming a plurality of hard mask patterns by selectively etching the pre-pattern layer;
removing the sacrificial mask pattern; and
etching the hard mask layer using the plurality of hard mask patterns as an etch mask,
wherein the hard mask layer includes a first layer contacting a lower portion of the sacrificial mask pattern and a second layer contacting a lower portion of the first layer; and
wherein a concentration of boron included in the first layer is lower than a concentration of boron included in the second layer.

14. The method according to claim 13, wherein the hard mask layer is formed by:
forming a fourth layer over the etch target layer;
forming a third layer over the fourth layer;
forming the second layer over the third layer; and
forming the first layer over the second layer.

15. The method according to claim 14, wherein
the boron concentration of the first layer is less than about 45 atomic %.

16. The method according to claim 14, wherein
the boron concentration of the second layer is greater than about 55 atomic %.

17. The method according to claim 14, wherein
the first layer and the second layer are formed at a temperature of about 400°C or higher.

18. A method of making a semiconductor device, the method comprising forming a hard mask layer disposed over a target layer,
and forming at least one hard mask pattern over the hard mask layer,
wherein the hard mask layer comprises a first layer, a second layer below the first layer, a third layer below the second layer, and a fourth layer between the third layer and the target layer,
wherein the first layer includes boron with a boron concentration of the first layer being less than about 45 atomic %,
wherein the second layer has a relatively higher density than the third layer, and
wherein the target layer is an etch target layer in which a semiconductor pattern is to be formed using the hard mask as an etch mask.

19. The method according to claim 18, wherein
the second layer includes boron with a boron concentration of the second layer being greater than about 55 atomic %.

20. The method according to claim 18, wherein
a density of the third layer is higher than a density of the fourth layer.
